(19) United States
(12) Patent Application Publication
(10) Pub. No.: US 2018/0286642 A1
(43) Pub. Date: Oct. 4, 2018

(54) ELECTROSTATIC CHUCK WITH FLEXIBLE WAFER TEMPERATURE CONTROL

(71) Applicant: Lam Research Corporation, Fremont, CA (US)

(72) Inventors: Alexander MATYUSHKIN, San Jose, CA (US); John Patrick HOLLAND, San Jose, CA (US); Mark H. WILCOXSON, Oakland, CA (US); Keith COMENDANT, Fremont, CA (US); Taner OZEL, Fremont, CA (US); Fangli HAO, Fremont, CA (US)

(21) Appl. No.: 15/942,099

(22) Filed: Mar. 30, 2018

Related U.S. Application Data
(60) Provisional application No. 62/480,232, filed on Mar. 31, 2017.

(51) Int. Cl. H01J 37/32; H01L 21/67; H01L 21/683; C23C 16/46

(52) U.S. Cl. CPC H01J 37/32715; H01L 21/67069; H01J 2237/002; C23C 16/466; H01L 21/6833

(57) ABSTRACT

An apparatus for processing a substrate is provided. A first coolant gas pressure system, a second coolant gas pressure system, a third coolant gas pressure system, and a fourth coolant gas pressure system are provided to provide independent gas pressures. An electrostatic chuck has a chuck surface with a center point and a radius and comprises a first plurality of coolant gas ports further than a first radius from a center point, a second plurality of coolant gas ports spaced between the first radius from the center point and a second radius from the center point, a third plurality of coolant gas ports spaced between the second radius from the center point and a third radius from the center point, and a fourth plurality of coolant gas ports is spaced within the third radius from the center point. An outer sealing band extends around the chuck surface.

### CROSS REFERENCE TO RELATED APPLICATION

This application claims the benefit of priority of U.S. Provisional Application No. 62/480,232 dated Mar. 31, 2017, which is incorporated herein by reference for all purposes.

### BACKGROUND

The disclosure relates to methods and apparatuses for forming semiconductor devices on a semiconductor wafer. More specifically, the disclosure relates to methods and apparatuses for providing wafer temperature control during semiconductor processing.

Semiconductor processing systems are used to process substrates such as semiconductor wafers. Example processes that may be performed on such systems include, but are not limited to, conductor etch, dielectric etch, atomic layer deposition, chemical vapor deposition, and/or other etch, deposition or cleaning processes. A substrate may be arranged on a substrate support including, for example, a pedestal, an electrostatic chuck (ESC), in a processing chamber of the semiconductor processing system.

### SUMMARY

To achieve the foregoing and in accordance with the purpose of the present disclosure, an apparatus for processing a substrate in a plasma processing chamber is provided. A first coolant gas pressure system is configured to provide a first coolant gas at a first pressure. A second coolant gas pressure system is configured to provide a second coolant gas at a second pressure independent of the first coolant gas pressure system. A third coolant gas pressure system is configured to provide a third coolant gas at a third pressure independent of the first coolant gas pressure system and the second coolant gas pressure system. A fourth coolant gas pressure system is configured to provide a fourth coolant gas at a fourth pressure independent of the first coolant gas pressure system, the second coolant gas pressure system, and the third coolant gas pressure system. An electrostatic chuck with a chuck surface has a center point and a circumference. A first plurality of coolant gas ports of the electrostatic chuck is connected to the first coolant gas pressure system, wherein each coolant gas port of the first plurality of coolant gas ports is further than a first radius from a center point. A second plurality of coolant gas ports of the electrostatic chuck is connected to the second coolant gas pressure system, wherein each coolant gas port of the second plurality of coolant gas ports is spaced between the first radius from the center point and a second radius from the center point, wherein the second radius is less than the first radius. A third plurality of coolant gas ports of the electrostatic chuck is connected to the third coolant gas pressure system, wherein each coolant gas port of the third plurality of coolant gas ports is spaced between the second radius from the center point and a third radius from the center point, wherein the third radius is less than the second radius. A fourth plurality of coolant gas ports of the electrostatic chuck is connected to the fourth coolant gas pressure system, wherein each coolant gas port of the fourth plurality of coolant gas ports is spaced a distance within the third radius from the center point. An outer sealing band extends around the circumference of the chuck surface, where the first plurality of coolant gas ports, the second plurality of coolant gas ports, the third plurality of coolant gas ports, and the fourth plurality of coolant gas ports are located the outer sealing band.

In another manifestation, an apparatus for processing a substrate in a plasma processing chamber is provided. An electrostatic chuck with a chuck surface having a circumference comprises a plurality of sealing bands located on the chuck surface, the plurality of sealing bands including an outer sealing band, a first inner band, a second inner band and a third inner banner, a plurality of cooling zones defined by the plurality of sealing bands, the plurality of cooling zones including a first radial cooling zone defined by the outer sealing band and the first inner band, a second radial cooling zone defined by the first inner band and the second inner band, a third radial cooling zone defined by the second inner band and the third inner band and a center cooling zone defined by the third inner band, and a plurality of coolant gas ports including first, second, third and fourth pluralities of coolant gas ports respectively located in the first radial, second radial, third radial and center cooling zones. A coolant gas supply system includes first, second, third and fourth control valves each configured to respectively provide coolant gases to the first, second, third and fourth pluralities of coolant gas ports at independent pressures.

In the above embodiment, the respective heights of the outer sealing band, the first inner band, the second inner band, and the third inner band may be about equal.

The electrostatic chuck may further comprise a plurality of bleed fixtures. Each fixture of the plurality of bleed fixtures may comprise at least one bleed hole and a sealing portion surrounding the at least one bleed hole. The at least one bleed hole may be connected to an exhaust.

A height of the outer sealing band may be higher than respective heights of the first inner band, the second inner band, and the third inner band. Heights of the first inner band, the second inner band, and the third inner band may be between one fourth and three fourths of a height of the outer sealing band. The outer sealing band may have a height of between 5 and 30 microns. The outer sealing band may have a notch in an upper outer portion of the outer sealing band.

A first pressure provided by the first control valve may be greater than a second pressure provided by the second control valve and the second pressure may be less than a third pressure provided by the third control valve and the third pressure may be greater than a fourth pressure provided by the fourth control valve.

The electrostatic chuck may further comprise a plurality of lift pin holes on the chuck surface.

In another manifestation, an electrostatic chuck with a chuck surface having a center point and a circumference is provided. A first plurality of coolant gas ports is connectable to a first coolant gas pressure system, wherein each coolant gas port of the first plurality of coolant gas ports is further than a first radius from the center point. A second plurality of coolant gas ports is connectable to a second coolant gas pressure system, wherein each coolant gas port of the second plurality of coolant gas ports is spaced between the first radius from the center point and a second radius from the center point, wherein the second radius is less than the first radius. A third plurality of coolant gas ports is connectable to a third coolant gas pressure system, wherein each coolant gas port of the third plurality of coolant gas ports is spaced between the second radius from the center point and a third radius from the center point, wherein the third radius is less than the second radius. A fourth plurality of coolant gas ports is connectable to a fourth coolant gas pressure system, wherein each coolant gas port of the fourth plurality of coolant gas ports is spaced a distance within the third radius from the center point. An outer sealing band extends around the circumference of the chuck surface, wherein the first plurality of coolant gas ports, the second plurality of coolant gas ports, the third plurality of coolant gas ports, and the fourth plurality of coolant gas ports are located within the outer sealing band.

In another manifestation, an electrostatic chuck with a chuck surface is provided. A plurality of sealing bands are located on the chuck surface, the plurality of sealing bands include an outer sealing band, a first inner band, a second inner band and a third inner band. A plurality of cooling zones are defined by the plurality of sealing bands, the plurality of cooling zones including a first radial cooling zone defined by the outer sealing band and the first inner band, a second radial cooling zone defined by the first inner band and the second inner band, a third radial cooling zone defined by the second inner band and the third inner band and a center cooling zone defined by the third inner band. A plurality of coolant gas ports include first, second, third and fourth pluralities of coolant gas ports respectively located in the first radial, second radial, third radial and center cooling zones.

For the above electrostatic chuck respective heights of the outer sealing band, the first inner band, the second inner band, and the third inner band may be about equal.

The electrostatic chuck may a plurality of bleed fixtures. Each of the plurality of bleed fixtures may comprise at least one bleed hole and a sealing portion surrounding the at least one bleed hole. The at least one bleed hole may be connectable to an exhaust.

For the above electrostatic chuck a height of the outer sealing band may be higher than respective heights of the first inner band, the second inner band, and the third inner band. The heights of the first inner band, the second inner band, and the third inner band may be between one fourth and three fourths of a height of the outer sealing band. The outer sealing band may have a height of between 5 and 30 microns. The outer sealing band may have a notch in an upper outer portion of the outer sealing band.

The first plurality of coolant gas ports may be configured to receive gas at a first pressure from a first control valve. The second plurality of coolant gas ports may be configured to receive gas at a second pressure from a second control valve, the first pressure being greater than the second pressure. The third plurality of coolant gas ports may be configured to receive gas at a third pressure from a third control valve, the second pressure being less than the third pressure. The fourth plurality of coolant gas ports may be configured to receive gas at a fourth pressure from a fourth control valve, the third pressure being greater than the fourth pressure.

The electrostatic chuck may further comprise a plurality of lift pin holes on the chuck surface.

These and other features of the present disclosure will be described in more details below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of a plasma processing chamber that may be used in an embodiment.

FIG. 2 is a schematic view of a computer system that may be used in practicing an embodiment.

FIG. 3 is a cross-sectional schematic side view of a top part of an ESC with a substrate in an embodiment.

FIG. 4 is a top view of a top part of the ESC shown in FIG. 3.

FIG. 5 is a schematic view of a control valve used in an embodiment.

FIG. 6 is a cross-sectional schematic side view of a top part of an ESC with a substrate in another embodiment.

FIG. 7 is a cross-sectional schematic side view of a top part of an ESC with a substrate in another embodiment.

FIG. 8 is a cross-sectional schematic side view of a top part of an ESC with a substrate in another embodiment.

FIG. 9 is a perspective view of a top part of an ESC in another embodiment.

FIG. 10 is a top view of a bleed fixture used in an embodiment.

FIG. 11 is an enlarged side cross-sectional view of the outer sealing band on the chuck surface of the embodiment shown in FIG. 9.

FIG. 12 is an enlarged side cross-sectional view of an outer sealing band of a chuck surface of another embodiment.

### DETAILED DESCRIPTION OF THE PREFERRED EMBODIMENTS

The present disclosure will now be described in detail with reference to a few exemplary embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Conventional designs of dielectric ESCs have one or two He zones which greatly restrict the ability to precisely control wafer temperature profile along the wafer radius.

Two-zone He ESCs also suffer from significant He pressure cross-talk between inner and outer zones. For example, if inner zone He pressure is set to 30 Torr, while outer zone He pressure is set to 80 Torr, there is significant cross-talk between the inner and outer zones with actual inner zone pressure higher than a corresponding desired set point and actual outer zone pressure lower than a corresponding desired set point. This effect manifests itself by increased He leak from the outer zone and zero or negative He leak from the inner zone. This effect means that wafer temperature is adversely impacted at high differential He pressure set points, thereby causing yield loss.

New semiconductor manufacturing processes require very tight control of etch rate (ER) and critical dimension (CD) uniformity, due to shrinking CD's to below 10 nm and greater effects of RF flux radial distribution. Among other parameters, temperature plays a major role in defining ER and CD uniformity. In dielectric etch, the main tuning knob for temperature control is He pressure under the wafer. Conventional ESC's use single or dual He zones for wafer temperature control. Neither of these designs provides sufficient radial control of the wafer temperature to keep up with modern process requirements.

Embodiments of the present disclosure solve the foregoing problems by: a) introducing multi-zone He control; b) ensuring accurate and nimble pressure control and temperature uniformity by introducing features, such as, He bleed holes in all He zones except for an outer zone.

Various embodiments provide multi-zone He control: introduction of four or more He zone controls enables an operator to setup desired He pressure and wafer temperature profiles for each step. Temperature profiling of the wafer compensates for variation in radial RF power distribution and ensures high process yield.

Bleed holes: a) provide accurate He pressure control within each zone by decreasing effects of He pressure cross-talk across zone boundary between zones with highly different pressure set points; b) enable sharp transition of He pressure and wafer temperature between zones; c) ensure desired temperature uniformity within zone by uniformly distributing He pressure under wafer in each zone; and d) enable quick He pressure transitions between process steps, as desired.

Bleed holes ensure that excessive He pressure is relieved or attenuated by dumping (“bleeding”) excess He into the processing chamber or foreline through one or more evacuation channels inside the ESC and/or ESC supporting structure. Amount of excessive flow and pressure in the He evacuation channel could be controlled by orifices in the channel or He pressure controller.

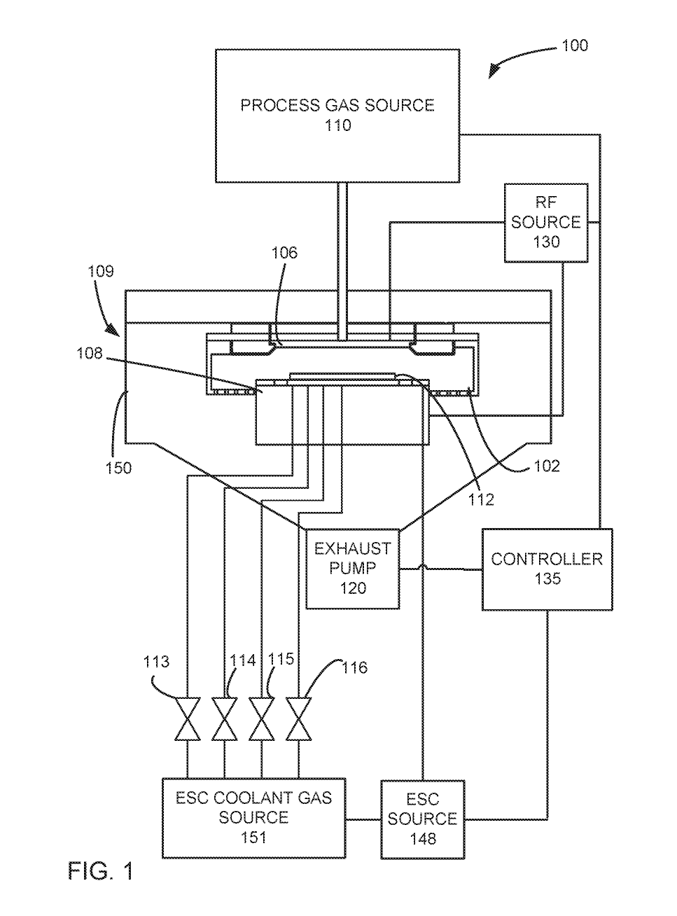

FIG. 1 is a schematic view of a plasma processing system 100 that may be used in an embodiment. The plasma processing system 100 comprises a gas distribution plate 106 providing a gas inlet and an electrostatic chuck (ESC) 108, within a processing chamber 109, enclosed by a chamber wall 150. Within the processing chamber 109, a substrate 112 is positioned on top of the ESC 108. The ESC 108 may provide a chucking voltage from the ESC source 148. A process gas source 110 is connected to the processing chamber 109 through the gas distribution plate 106. An ESC coolant gas source 151 provides an ESC coolant gas to a number of control valves including a first control valve 113, a second control valve 114, a third control valve 115, and a fourth control valve 116. The first control valve 113 provides ESC coolant gas to a first cooling zone of the ESC 108. The second control valve 114 provides ESC coolant gas to a second cooling zone of the ESC 108. The third control valve 115 provides ESC coolant gas to a third cooling zone of the ESC 108. The fourth control valve 116 provides ESC coolant gas to a fourth cooling zone of the ESC 108. A radio frequency (RF) source 130 provides RF power to the ESC 108, which acts as a lower electrode, and/or the gas distribution plate 106, which acts as an upper electrode. In an exemplary embodiment, 400 kHz, 2 MHz, 60 MHz, and 27 MHz power sources make up the RF source 130. In this embodiment, one generator is provided for each frequency. In other embodiments, multiple generators may be in separate RF sources, or separate RF generators may be connected to different electrodes. For example, the upper electrode may have inner and outer electrodes connected to different RF sources. Other arrangements of RF sources and electrodes may be used in other embodiments, for example, in one embodiment, the upper electrodes may be grounded. A controller 135 is controllably connected to the RF source 130, the ESC source 148, an exhaust pump 120, the ESC coolant gas source 151, and the process gas source 110. The processing chamber 109 can be a CCP (capacitive coupled plasma) reactor, commonly used to etch dielectric materials) or an ICP (inductive coupled plasma) reactor, commonly used to etch conductive materials or silicon.

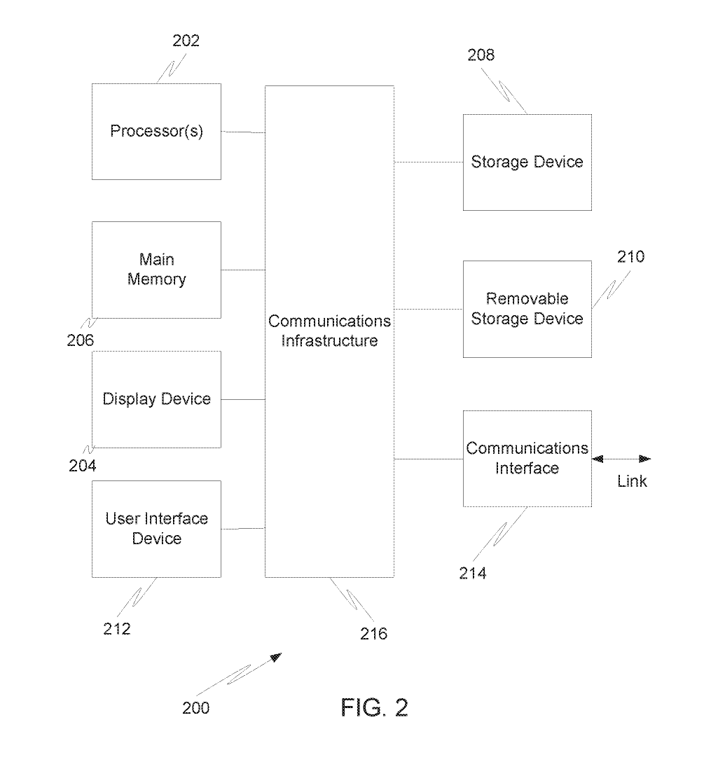

FIG. 2 is a high level block diagram showing a computer system 200, which is suitable for implementing a controller 135 used in embodiments. The computer system 200 may have many physical forms ranging from an integrated circuit, a printed circuit board, and a small handheld device up to a huge super computer. The computer system 200 includes one or more processors 202, and further can include an electronic display device 204 (for displaying graphics, text, and other data), a main memory 206 (e.g., random access memory (RAM)), storage device 208 (e.g., hard disk drive), removable storage device 210 (e.g., optical disk drive), user interface devices 212 (e.g., keyboards, touch screens, keypads, mice or other pointing devices, etc.), and a communications interface 214 (e.g., wireless network interface). The communications interface 214 allows software and data to be transferred between the computer system 200 and external devices via a link. The system may also include a communications infrastructure 216 (e.g., a communications bus, cross-over bar, or network) to which the aforementioned devices/modules are connected.

Information transferred via communications interface 214 may be in the form of signals such as electronic, electromagnetic, optical, or other signals capable of being received by communications interface 214, via a communications link that carries signals and may be implemented using wire or cable, fiber optics, a phone line, a cellular phone link, a radio frequency link, and/or other communications channels. With such a communications interface 214, it is contemplated that the one or more processors 202 might receive information from a network, or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

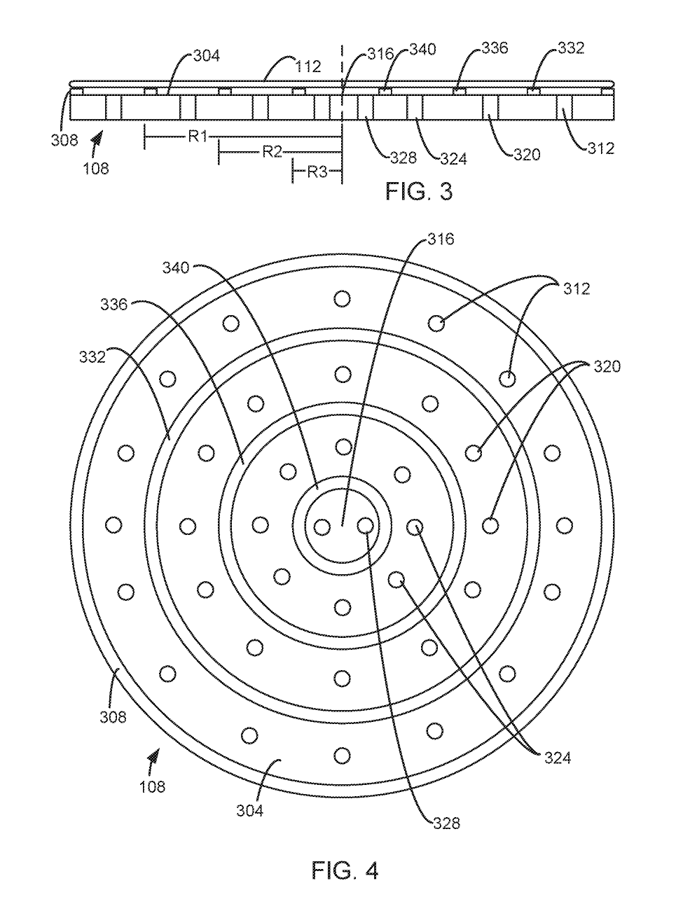

FIG. 3 is a cross-sectional schematic side view of a top part of the ESC 108 with the substrate 112 located thereon in an embodiment. FIG. 3 is not drawn to scale in order to more clearly illustrate certain aspects of the embodiment. The top part of the ESC 108 forms a chuck surface 304. FIG. 4 is a top view of the chuck surface 304 of the ESC 108. In this embodiment, an outer sealing band 308 extends around a circumference of the chuck surface 304, as shown.

A first plurality of coolant gas ports 312 is situated further than a first radius R1 from a center point 316. The first plurality of coolant gas ports 312 is in fluid contact with the first control valve 113, which provides a first pressure to the first plurality of coolant gas ports 312.

A second plurality of coolant gas ports 320 is situated between a second radius R2 and the first radius R1 from the center point 316. The second plurality of coolant gas ports 320 is in fluid contact with the second control valve 114, which provides a second pressure to the second plurality of coolant gas ports 320. The second pressure may be different from the first pressure provided to the first plurality of coolant gas ports 312.

A third plurality of coolant gas ports 324 is situated between a third radius R3 and the second radius R2 from the center point 316. The third plurality of coolant gas ports 324 is in fluid contact with the third control valve 115, which provides a third pressure to the third plurality of coolant gas ports 324. The third pressure may be different from the second pressure provided to the second plurality of coolant gas ports 320.

A fourth plurality of coolant gas ports 328 is situated less than the third radius R3 from the center point 316. The fourth plurality of coolant gas ports 328 is in fluid contact with the fourth control valve 116, which provides a fourth pressure to the fourth plurality of coolant gas ports 328. The fourth pressure may be different from the third pressure provided to the third plurality of coolant gas ports 324.

A first inner band 332 is situated between the first plurality of coolant gas ports 312 and the second plurality of coolant gas ports 320. A second inner band 336 is situated between the second plurality of coolant gas ports 320 and the third plurality of coolant gas ports 324. A third inner band 340 is situated between the third plurality of coolant gas ports 324 and fourth plurality of coolant gas ports 328.

The first plurality of coolant gas ports 312 is situated between the outer sealing band 308 and the first inner band 332. The second plurality of coolant gas ports 320 is situated between the first inner band 332 and the second inner band 336. The third plurality of coolant gas ports 324 is situated between the second inner band 336 and the third inner band 340. The fourth plurality of coolant gas ports 328 is situated within the third inner band 340.

In this embodiment, the region between the outer sealing band 308 and the first inner band 332 defines a first cooling zone also called a first radial cooling zone. The region between the first inner band 332 and the second inner band 336 defines a second cooling zone also called a second radial cooling zone. The region between the second inner band 336 and the third inner band 340 defines a third cooling zone also called a third radial cooling zone. The region inside the third inner band 340 defines a fourth cooling zone also called a center cooling zone.

The first inner band 332, the second inner band 336, the third inner band 340, and the outer sealing band 308 have a height of approximately 10 microns. The first inner band 332, the second inner band 336, the third inner band 340, and the outer sealing band 308 are approximately equal in height. The first inner band 332, the second inner band 336, the third inner band 340, and the outer sealing band 308 contact the substrate 112 forming a seal between adjacent cooling zones, thereby minimizing gas leakage between adjacent cooling zones.

In an embodiment, the first control valve 113 provides He coolant gas at a pressure of 80 Torr to the first cooling zone through the first plurality of coolant gas ports 312. The second control valve 114 provides He coolant gas at a pressure of 30 Torr to the second cooling zone through the second plurality of coolant gas ports 320. The third control valve 115 provides He coolant gas at a pressure of 80 Torr to the third cooling zone through the third plurality of coolant gas ports 324. The fourth control valve 116 provides He coolant gas at a pressure of 30 Torr to the fourth cooling zone through the fourth plurality of coolant gas ports 328. For each cooling zone, the He coolant gas is provided at a temperature of about 20° C.

In this embodiment, the outer sealing band 308 forms a closed loop that encloses an area of the chuck surface 304 that is at least 90% of the total area of the chuck surface 304. The first inner band 332, the second inner band 336, and the third inner band 340 also form closed loops that enclose areas of the chuck surface 304. In this embodiment, the outer sealing band 308, first inner band 332, the second inner band 336, and the third inner band 340 each form concentric substantially circular loops with a center at the center point 316. The center point 316 is the center of the chuck surface 304.

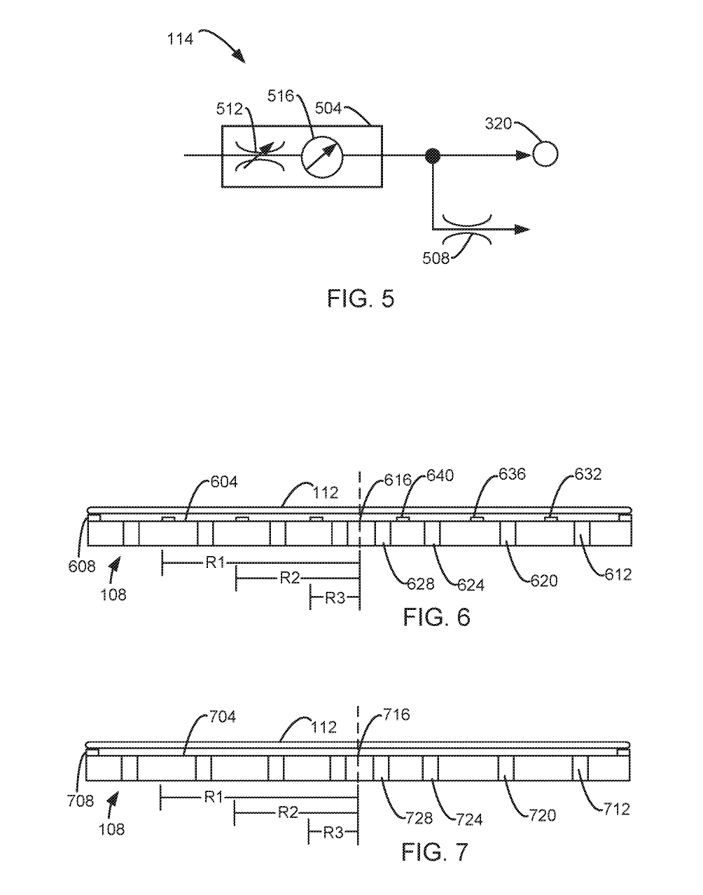

FIG. 5 is a schematic view of the second control valve 114 and one of the second plurality of coolant gas ports 320. The second control valve 114 comprises a mass flow controller unit (MFC) 504, which provides He coolant gas to the second plurality of coolant gas ports 320 and a flow control valve 508 connected to exhaust. In this embodiment, the MFC 504 comprises a control valve 512 and a pressure setup and control 516. The pressure setup and control 516 is used to set a specified pressure and maintain the pressure at the specified pressure. The output of the MFC 504 is connected to the second plurality of coolant gas ports 320. A first end of the flow control valve 508 is connected between the MFC 504 and the second plurality of coolant gas ports 320. A second end of the flow control valve 508 is connected to exhaust or dump.

In one embodiment, since the second cooling zone is kept at a pressure of 30 Torr and the adjacent first cooling zone and third cooling zone are kept at a pressure of 80 Torr, gas from the first cooling zone and third cooling zone may leak into the second cooling zone, which would tend to increase the pressure in the second cooling zone. The flow control valve 508 is set to 30 Torr. When gas from the first cooling zone and third cooling zone leak into the second cooling zone and increase pressure in the second cooling zone above 30 Torr, the excess gas passes through the flow control valve 508 to exhaust, thereby maintaining the pressure in the second cooling zone close to 30 Torr. In this embodiment, the first control valve 113, the third control valve 115, and the fourth control valve 116 have a similar configuration to the second control valve 114. The first control valve 113 provides a first coolant gas pressure system. The second control valve 114 provides a second coolant gas pressure system. The third control valve 115 provides a third coolant gas pressure system. The fourth control valve 116 provides a fourth coolant gas pressure system.

In operation, the four separate cooling zones and the varying pressures provided at the first, second, third, and fourth pluralities of coolant gas ports 312, 320, 324, and 326, allow creating a desired wafer temperature profile by setting predetermined/desired He pressures to each zone at every step of the etch process. The improved wafer temperature profile provides a more uniform etch across the substrate 112.

FIG. 6 is a cross-sectional schematic side view of a top part of the ESC 108 with the substrate 112 located thereon in another embodiment. FIG. 6 is not drawn to scale in order to more clearly illustrate certain aspects of the embodiment. The top part of the ESC 108 forms a chuck surface 604. In this embodiment, an outer sealing band 608 extends around a circumference of the chuck surface 604.

A first plurality of coolant gas ports 612 is situated further than a first radius R1 from a center point 616. The first plurality of coolant gas ports 612 are in fluid contact with the first control valve 113, which provides a first pressure to the first plurality of coolant gas ports 612.

A second plurality of coolant gas ports 620 is situated between a second radius R2 and the first radius R1 from the center point 616. The second plurality of coolant gas ports 620 is in fluid contact with the second control valve 114, which provides a second pressure to the second plurality of coolant gas ports 620. The second pressure may be different from the first pressure provided to the first plurality of coolant gas ports 612.

A third plurality of coolant gas ports 624 is situated between a third radius R3 and the second radius R2 from the center point 616. The third plurality of coolant gas ports 624 is in fluid contact with the third control valve 115, which provides a third pressure to the third plurality of coolant gas ports 624. The third pressure may be different from the second pressure provided to the second plurality of coolant gas ports 620.

A fourth plurality of coolant gas ports 628 is situated less than the third radius R3 from the center point 616. The fourth plurality of coolant gas ports 628 is in fluid contact with the fourth control valve 116, which provides a fourth pressure to the fourth plurality of coolant gas ports 628. The fourth pressure may be different from the third pressure provided to the third plurality of coolant gas ports 624.

A first inner band 632 is situated between the first plurality of coolant gas ports 612 and the second plurality of coolant gas ports 620. A second inner band 636 is situated between the second plurality of coolant gas ports 620 and the third plurality of coolant gas ports 624. A third inner band 640 is situated between the third plurality of coolant gas ports 624 and fourth plurality of coolant gas ports 628.

The first plurality of coolant gas ports 612 is situated between the outer sealing band 608 and the first inner band 632. The second plurality of coolant gas ports 620 is situated between the first inner band 632 and the second inner band 636. The third plurality of coolant gas ports 624 is situated between the second inner band 636 and the third inner band 640. The fourth plurality of coolant gas ports 628 is situated within the third inner band 640.

In this embodiment, the region between the outer sealing band 608 and the first inner band 632 defines a first cooling zone. The region between the first inner band 632 and the second inner band 636 defines a second cooling zone. The region between the second inner band 636 and the third inner band 640 defines a third cooling zone. The region inside the third inner band 640 defines a fourth cooling zone.

The first inner band 632, the second inner band 636, and the third inner band 640 generally have the same height, which, in one embodiment, is a height of approximately 5 microns. In at least one other embodiment, one or more of the first inner band 632, the second inner band 636, and the third inner band 640 have different heights relative to the others. The outer sealing band 608 generally has a height that is higher than that of the first inner band 632, the second inner band 636 and the third inner band 640. In one embodiment, the outer sealing band has a height of approximately 10 microns. The first inner band 632, the second inner band 636, and the third inner band 640 are approximately half the height of the outer sealing band 608. In other embodiments, the first inner band 632, the second inner band 636, and the third inner band 640 may be between one fourth and three fourths the height of the outer sealing band 608. The first inner band 632, the second inner band 636, and the third inner band 640 provide partial sealing between adjacent cooling zones. However, since the first inner band 632, the second inner band 636, and the third inner band 640 have a lower height than the outer sealing band 608, the first inner band 632, the second inner band 636, and the third inner band 640 do not contact the substrate 112, thereby allowing some gas to pass between adjacent cooling zones via a gap between the substrate 112 and the corresponding inner band. Because the first inner band 632, the second inner band 636, and the third inner band 640 do not contact the substrate 112, the first inner band 632, the second inner band 636, and the third inner band 640 do not affect the temperature of the substrate 112 as much as if the first inner band 632, the second inner band 636, and the third inner band 640 contacted the substrate 112. As a result, the temperature of the substrate 112 is more uniform. The increased temperature uniformity may improve wafer to wafer repeatability and etch uniformity. There is also less RF coupling nonuniformity due to the smaller height of the first, second, and third inner bands 632, 636, 640.

FIG. 7 is a cross-sectional schematic side view of a top part of the ESC 108 with the substrate 112 located thereon in another embodiment. The top part of the ESC 108 forms a chuck surface 704. In this embodiment, an outer sealing band 708 extends around a circumference of the chuck surface 704.

A first plurality of coolant gas ports 712 is situated further than a first radius R1 from a center point 716. The first plurality of coolant gas ports 712 are in fluid contact with the first control valve 113, which provides a first pressure to the first plurality of coolant gas ports 712.

A second plurality of coolant gas ports 720 is situated between a second radius R2 and the first radius R1 from the center point 716. The second plurality of coolant gas ports 720 is in fluid contact with the second control valve 114, which provides a second pressure to the second plurality of coolant gas ports 720. The second pressure may be different from the first pressure provided to the first plurality of coolant gas ports 712.

A third plurality of coolant gas ports 724 is situated between a third radius R3 and the second radius R2 from the center point 716. The third plurality of coolant gas ports 724 is in fluid contact with the third control valve 115, which provides a third pressure to the third plurality of coolant gas ports 724. The third pressure may be different from the second pressure provided to the second plurality of coolant gas ports 720.

A fourth plurality of coolant gas ports 728 is situated less than the third radius R3 from the center point 716. The fourth plurality of coolant gas ports 728 is in fluid contact with the fourth control valve 116, which provides a fourth pressure to the fourth plurality of coolant gas ports 728. The fourth pressure may be different from the third pressure provided to the third plurality of coolant gas ports 724.

The outer sealing band 708 has a height of approximately 10 microns. In this embodiment, the ESC 108 does not have any inner bands. As a result, there is not any separation between gases emanating from adjacent coolant gas ports. Since this embodiment does not have inner bands and thus the substrate temperature would not be influenced by the presence of inner bands, the substrate 112 temperature may be more uniform. The increased temperature uniformity may improve wafer to wafer repeatability and etch uniformity. In addition, better RF coupling uniformity results in better etch rate uniformity.

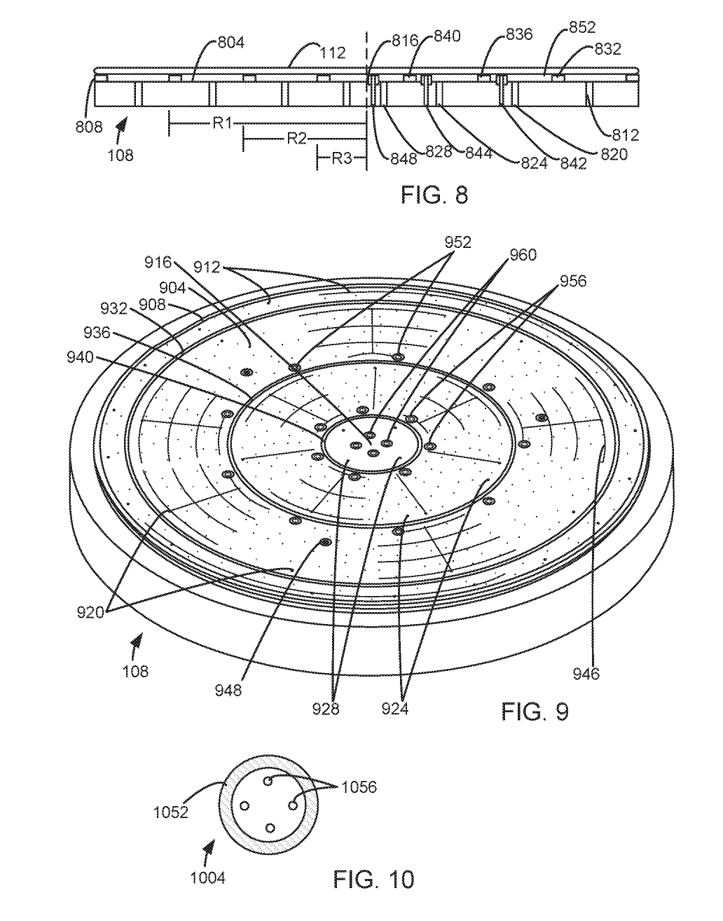

FIG. 8 is a cross-sectional schematic side view of a top part of the ESC 108 with the substrate 112 in another embodiment. FIG. 8 is not drawn to scale in order to more clearly illustrate certain aspects of the embodiment. The top part of the ESC 108 forms a chuck surface 804. In this embodiment, an outer sealing band 808 extends around a circumference of the chuck surface 804.

A first plurality of coolant gas ports 812 is situated further than a first radius R1 from a center point 816. The first plurality of coolant gas ports 812 are in fluid contact with the first control valve 113, which provides a first pressure to the first plurality of coolant gas ports 812.

A second plurality of coolant gas ports 820 is situated between a second radius R2 and the first radius R1 from the center point 816. The second plurality of coolant gas ports 820 is in fluid contact with the second control valve 114, which provides a second pressure to the second plurality of coolant gas ports 820. The second pressure may be different from the first pressure provided to the first plurality of coolant gas ports 812.

A third plurality of coolant gas ports 824 is situated between a third radius R3 and the second radius R2 from the center point 816. The third plurality of coolant gas ports 824 is in fluid contact with the third control valve 115, which provides a third pressure to the third plurality of coolant gas ports 824. The third pressure may be different from the second pressure provided to the second plurality of coolant gas ports 820.

A fourth plurality of coolant gas ports 828 is situated less than the third radius R3 from the center point 816. The fourth plurality of coolant gas ports 828 is in fluid contact with the fourth control valve 116, which provides a fourth pressure to the fourth plurality of coolant gas ports 828. The fourth pressure may be different from the third pressure provided to the third plurality of coolant gas ports 824.

A first inner band 832 is situated between the first plurality of coolant gas ports 812 and the second plurality of coolant gas ports 820. A second inner band 836 is situated between the second plurality of coolant gas ports 820 and the third plurality of coolant gas ports 824. A third inner band 840 is situated between the third plurality of coolant gas ports 824 and the fourth plurality of coolant gas ports 828.

The first plurality of coolant gas ports 812 is situated between the outer sealing band 808 and the first inner band 832. The second plurality of coolant gas ports 820 is situated between the first inner band 832 and the second inner band 836. The third plurality of coolant gas ports 824 is situated between the second inner band 836 and the third inner band 840. The fourth plurality of coolant gas ports 828 is situated within the third inner band 840.

In this embodiment, the region between the outer sealing band 808 and the first inner band 832 defines a first cooling zone. The region between the first inner band 832 and the second inner band 836 defines a second cooling zone. The region between the second inner band 836 and the third inner band 840 defines a third cooling zone. The region inside the third inner band 840 defines a fourth cooling zone. The first inner band 832, the second inner band 836, the third inner band 840, and the outer sealing band 808 have a height of approximately 10 microns.

In the second cooling zone, a first bleed fixture 842 is situated between the first inner band 832 and the second inner band 836. In the third cooling zone, a second bleed fixture 844 is situated between the second inner band 836 and the third inner band 840. In the fourth cooling zone, a third bleed fixture 848 is situated within the third inner band 840. The first, second and third bleed fixtures 842, 844, 848 may each include one or more bleed holes. Since FIG. 8 is a cross-sectional side view, only one bleed fixture is shown in the second, third, and fourth cooling zones. However, various embodiments may have more than one bleed fixture in each of the second, third, and fourth cooling zones. In this example, there are no bleed fixtures in the first cooling zone, because any He leak via the outer sealing band 808 would be to vacuum. The first, second, and third bleed fixtures 842, 844, 848 are connected to vacuum.

The first inner band 832, the second inner band 836, the third inner band 840, and the outer sealing band 808 are approximately equal in height. The first inner band 832, the second inner band 836, and the third inner band 840 provide sealing between adjacent cooling zones.

In this example, the first plurality of coolant gas ports 812 provide He at a pressure of 80 Torr, so that the first cooling zone has a pressure of about 80 Torr. The second plurality of coolant gas ports 820 provide He at a pressure of 30 Torr, so that the second cooling zone has a pressure of about 30 Torr. The third plurality of coolant gas ports 824 provide He at a pressure of 80 Torr, so that the third cooling zone has a pressure of about 80 Torr. The fourth plurality of coolant gas ports 828 provide He at a pressure of 30 Torr, so that the fourth cooling zone has a pressure of about 30 Torr. Since adjacent cooling zones are at different pressures, gas from the cooling zone at a higher pressure tends to leak into the cooling zone at a lower pressure, thereby increasing the pressure in the cooling zone at a lower pressure. The first, second, and third bleed fixtures 842, 844, 848 allow the respective cooling zones to maintain their desired pressures. Pressure caused by gasses leaked into the second, third and fourth cooling zones is relieved or attenuated by diverting or dumping the excess gases through the first, second, and third bleed fixtures 842, 844, 848. Cooling gas from the first cooling zone may be allowed to bleed past the outer sealing band 808 so as to maintain the desired pressure in the first cooling zone. The improved pressure control provided by the first, second, and third bleed fixtures 842, 844, 848 provide for improved etch uniformity.

In this embodiment, a first pressure provided by the first control valve 113 is greater than a second pressure provided by the second control valve 114. The second pressure is less than a third pressure provided by the third control valve 115. The third pressure is greater than a fourth pressure provided by the fourth control valve 116. In other embodiments, other pressure relationships may be provided. For example the first pressure may be greater than the second pressure. The second pressure may be greater than the third pressure. The third pressure may be greater than the fourth pressure.

FIG. 9 is a perspective view of a top part of the ESC 108 in another embodiment. The top part of the ESC 108 forms a chuck surface 904. In this embodiment, an outer sealing band 908 extends around a circumference of the chuck surface 904.

A first plurality of coolant gas ports 912 is situated inside the outer sealing band 908. The first plurality of coolant gas ports 912 are in fluid contact with the first control valve 113, which provides a first pressure to the first plurality of coolant gas ports 912. A first inner band 932 is between the first plurality of coolant gas ports 912 and a center point 916.

A second plurality of coolant gas ports 920 is situated inside the first inner band 932. The second plurality of coolant gas ports 920 is in fluid contact with the second control valve 114 and provides a second pressure to the second plurality of coolant gas ports 920. The second pressure is different from the first pressure. A second inner band 936 is situated between the second plurality of coolant gas ports 920 and the center point 916.

A third plurality of coolant gas ports 924 is situated inside the second inner band 936. The third plurality of coolant gas ports 924 is in fluid contact with the third control valve 115 and provides a third pressure to the third plurality of coolant gas ports 924. The third pressure is different from the second pressure. A third inner band 940 is between the third plurality of coolant gas ports 924 and the center point 916.

A fourth plurality of coolant gas ports 928 is situated within the third inner band 940. The fourth plurality of coolant gas ports 928 is in fluid contact with the fourth control valve 116 and provides a fourth pressure to the fourth plurality of coolant gas ports 928. The fourth pressure is different from the third pressure. The chuck surface 904 has three lift pin holes 948 to accommodate lift pins (not shown). The lift pins are used for lifting the substrate 112 from the chuck surface 904.

In this embodiment, the region between the outer sealing band 908 and the first inner band 932 defines a first cooling zone. The region between the first inner band 932 and the second inner band 936 defines a second cooling zone. The region between the second inner band 936 and the third inner band 940 defines a third cooling zone. The region inside the third inner band 940 defines a fourth cooling zone. The first inner band 932, the second inner band 936, the third inner band 940, and the outer sealing band 908 have a height of approximately 10 microns.

In the second cooling zone, a first plurality of bleed fixtures 952 is situated between the first inner band 932 and the second inner band 936. In the third cooling zone, a second plurality of bleed fixtures 956 is situated between the second inner band 936 and the third inner band 940. In the fourth cooling zone, a third plurality of bleed fixtures 960 is within the third inner band 940.

FIG. 10 is a top view of a bleed fixture 1004 of the first, second, and third pluralities of bleed fixtures 952, 956, 960. The bleed fixture 1004 comprises a raised sealing portion 1052 and four bleed holes 1056. The raised sealing portion 1052 provides a narrow gap between the top of the raised sealing portion 1052 and the substrate (not shown), so that the flow rate of the cooling gas to the bleed holes 1056 is at a rate to maintain a desired pressure profile.

Grooves 946 extend between the second plurality of coolant gas ports 920 and the first plurality of bleed fixtures 952 in order to evenly distribute the coolant gas within the second cooling zone. In this embodiment, there are several concentric circles of the second plurality of coolant gas ports 920 in the second cooling zone in order to provide an even distribution of the second plurality of coolant gas ports 920 within the second cooling gas zones. Not all of the second plurality of coolant gas ports 920 and all of the grooves 946 are shown in order to more clearly illustrate other features. In addition, the third plurality of coolant gas ports 924 is evenly distributed within the third cooling zone. There are grooves between the third plurality of coolant gas ports 924. Not all of the third plurality of coolant gas ports 924 and all of the grooves are shown in order to more clearly illustrate other features. In addition, the fourth plurality of coolant gas ports 928 is evenly distributed within the fourth cooling zone. There are grooves between the fourth plurality of coolant gas ports 928. Not all of the fourth plurality of coolant gas ports 928 and all of the grooves are shown in order to more clearly illustrate other features. In addition, the first plurality of coolant gas ports 912 is evenly distributed within the first cooling zone. There are grooves between the first plurality of coolant gas ports 912. Not all of the first plurality of coolant gas ports 912 and all of the grooves are shown in order to more clearly illustrate other features.

In various embodiments, the outer sealing band 908 has a height between 5 to 30 microns. More preferably, the outer sealing band 908 has a height between 7 to 15 microns. In various embodiments, the first inner band 932, the second inner band 936, and the third inner band 940 may have a height equal to the outer sealing band 908 to a height of 0 microns. More preferably, the height of the first inner band 932, the second inner band 936, and the third inner band 940 is in the range from one quarter the height of the outer sealing band 908 to approximately equal to the height of the outer sealing band 908.

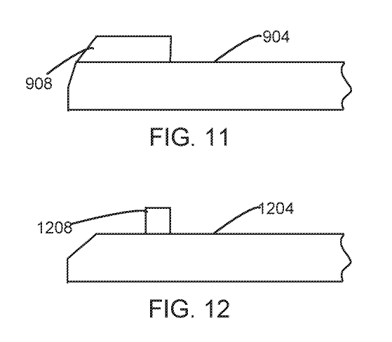

FIG. 11 is an enlarged side cross-sectional view of the outer sealing band 908 on the chuck surface 904 of the embodiment shown in FIG. 9, The contact between the substrate and the outer sealing band 908 affects the temperature of the substrate. During use, the upper outer portion of the outer sealing band 908 is gradually etched away. As a result, the influence of substrate temperature by the outer sealing band 908 changes over time. This substrate temperature change may cause changes from wafer to wafer.

FIG. 12 is an enlarged side cross-sectional view of an outer sealing band 1208 of a chuck surface 1204 of another embodiment. In this embodiment, the upper outer corner of the outer sealing band 1208 has been removed forming a notch in the upper outer portion of the outer sealing band 1208, as shown. As a result, only the upper inner portion (and a smaller area compared to the outer sealing band 908 as shown in FIG. 11) of the outer sealing band 1208 makes contact with the substrate (not shown). Since only the upper inner portion (and a smaller area) of the outer sealing band 1208 makes contact with the substrate, there is less temperature change from wafer to wafer.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the disclosure be interpreted as including all such alterations, modifications, permutations, and various substitute equivalents as fall within the true spirit and scope of the present disclosure.

What is claimed is:

1. An apparatus for processing a substrate in a plasma processing chamber, comprising:
a first coolant gas pressure system configured to provide a first coolant gas at a first pressure;
a second coolant gas pressure system configured to provide a second coolant gas at a second pressure independent of the first coolant gas pressure system;
a third coolant gas pressure system configured to provide a third coolant gas at a third pressure independent of the first coolant gas pressure system and the second coolant gas pressure system;
a fourth coolant gas pressure system configured to provide a fourth coolant gas at a fourth pressure independent of the first coolant gas pressure system, the second coolant gas pressure system, and the third coolant gas pressure system; and
an electrostatic chuck with a chuck surface having a center point and a circumference, the electrostatic chuck further comprising:
a first plurality of coolant gas ports connected to the first coolant gas pressure system, wherein each coolant gas port of the first plurality of coolant gas ports is further than a first radius from the center point;
a second plurality of coolant gas ports connected to the second coolant gas pressure system, wherein each coolant gas port of the second plurality of coolant gas ports is spaced between the first radius from the center point and a second radius from the center point, wherein the second radius is less than the first radius;
a third plurality of coolant gas ports connected to the third coolant gas pressure system, wherein each coolant gas port of the third plurality of coolant gas ports is spaced between the second radius from the center point and a third radius from the center point, wherein the third radius is less than the second radius;
a fourth plurality of coolant gas ports connected to the fourth coolant gas pressure system, wherein each coolant gas port of the fourth plurality of coolant gas ports is spaced a distance within the third radius from the center point; and
an outer sealing band extending around the circumference of the chuck surface, wherein the first plurality of coolant gas ports, the second plurality of coolant gas ports, the third plurality of coolant gas ports, and the fourth plurality of coolant gas ports are located within the outer sealing band.

2. The apparatus, as recited in claim 1, the electrostatic chuck further comprising a first inner band, wherein the first inner band is placed between the first plurality of coolant gas ports and the second plurality of coolant gas ports.

3. The apparatus, as recited in claim 2, the electrostatic chuck further comprising a second inner band, wherein the second inner band is placed between the second plurality of coolant gas ports and the third plurality of coolant gas ports.

4. The apparatus, as recited in claim 3, the electrostatic chuck further comprising a third inner band, wherein the third inner band is placed between the third plurality of coolant gas ports and the fourth plurality of coolant gas ports.

5. The apparatus, as recited in claim 4, wherein respective heights of the outer sealing band, the first inner band, the second inner band, and the third inner band are about equal.

6. The apparatus, as recited in claim 5, the electrostatic chuck further comprising a plurality of bleed fixtures.

7. The apparatus, as recited in claim 6, wherein each fixtures of the plurality of bleed fixtures comprises:
at least one bleed hole; and
a sealing portion surrounding the at least one bleed hole.

8. The apparatus, as recited in claim 7, wherein the at least one bleed hole is connected to an exhaust.

9. The apparatus, as recited in claim 4, wherein a height of the outer sealing band is higher than respective heights of the first inner band, the second inner band, and the third inner band.

10. The apparatus, as recited in claim 4, wherein heights of the first inner band, the second inner band, and the third inner band are between one fourth and three fourths of a height of the outer sealing band.

11. The apparatus, as recited in claim 1, wherein the first pressure provided by the first coolant gas pressure system is greater than the second pressure provided by the second coolant gas pressure system and the second pressure is less than the third pressure provided by the third coolant gas pressure system and the third pressure is greater than the fourth pressure provided by the fourth coolant gas pressure system.

12. The apparatus, as recited in claim 1, wherein the outer sealing band has a height of between 5 and 30 microns.

13. The apparatus, as recited in claim 1, the electrostatic chuck further comprising a plurality of lift pin holes on the chuck surface.

14. The apparatus, as recited in claim 1, wherein the outer sealing band has a notch in an upper outer portion of the outer sealing band.

15. The apparatus, as recited in claim 1, wherein the first coolant gas pressure system comprises:
a mass flow controller unit connected to the first plurality of coolant gas ports; and
a flow control valve with a first end connected between the mass flow controller unit and the first plurality of coolant gas ports.

16. An electrostatic chuck with a chuck surface having a center point and a circumference, comprising:
a first plurality of coolant gas ports connectable to a first coolant gas pressure system, wherein each coolant gas port of the first plurality of coolant gas ports is further than a first radius from the center point;
a second plurality of coolant gas ports connectable to a second coolant gas pressure system, wherein each coolant gas port of the second plurality of coolant gas ports is spaced between the first radius from the center point and a second radius from the center point, wherein the second radius is less than the first radius;
a third plurality of coolant gas ports connectable to a third coolant gas pressure system, wherein each coolant gas port of the third plurality of coolant gas ports is spaced between the second radius from the center point and a third radius from the center point, wherein the third radius is less than the second radius;
a fourth plurality of coolant gas ports connectable to a fourth coolant gas pressure system, wherein each coolant gas port of the fourth plurality of coolant gas ports is spaced a distance within the third radius from the center point; and
an outer sealing band extending around the circumference of the chuck surface, wherein the first plurality of coolant gas ports, the second plurality of coolant gas ports, the third plurality of coolant gas ports, and the fourth plurality of coolant gas ports are located within the outer sealing band.

17. The electrostatic chuck, as recited in claim 16, further comprising a first inner band, wherein the first inner band is placed between the first plurality of coolant gas ports and the second plurality of coolant gas ports.

18. The electrostatic chuck, as recited in claim 17, further comprising a second inner band, wherein the second inner band is placed between the second plurality of coolant gas ports and the third plurality of coolant gas ports.

19. The electrostatic chuck, as recited in claim 18, further comprising a third inner band, wherein the third inner band is placed between the third plurality of coolant gas ports and the fourth plurality of coolant gas ports.

20. The electrostatic chuck, as recited in claim 19, wherein respective heights of the outer sealing band, the first inner band, the second inner band, and the third inner band are about equal.

21. The electrostatic chuck, as recited in claim 20, further comprising a plurality of bleed fixtures.

22. The electrostatic chuck, as recited in claim 21, wherein each of the plurality of bleed fixtures comprises:
at least one bleed hole; and
a sealing portion surrounding the at least one bleed hole.

23. The electrostatic chuck, as recited in claim 22, wherein the at least one bleed hole is connectable to an exhaust.

24. The electrostatic chuck, as recited in claim 19, wherein a height of the outer sealing band is higher than respective heights of the first inner band, the second inner band, and the third inner band.

25. The electrostatic chuck, as recited in claim 19, wherein heights of the first inner band, the second inner band, and the third inner band are between one fourth and three fourths of a height of the outer sealing band.

26. The electrostatic chuck, as recited in claim 16, wherein the first plurality of coolant gas ports is configured to receive gas at a first pressure from the first coolant gas pressure system;
wherein the second plurality of coolant gas ports is configured to receive gas at a second pressure from the second coolant gas pressure system, the first pressure being greater than the second pressure;
wherein the third plurality of coolant gas ports is configured to receive gas at a third pressure from the third coolant gas pressure system, the second pressure being less than the third pressure; and
wherein the fourth plurality of coolant gas ports is configured to receive gas at a fourth pressure from the fourth coolant gas pressure system, the third pressure being greater than the fourth pressure.

27. The electrostatic chuck, as recited in claim 16, wherein the outer sealing band has a height of between 5 and 30 microns.

28. The electrostatic chuck, as recited in claim 16, further comprising a plurality of lift pin holes on the chuck surface.

29. The electrostatic chuck, as recited in claim 16, wherein the outer sealing band has a notch in an upper outer portion of the outer sealing band.
